(19) United States
(12) Patent Application Publication
(10) Pub. No.: US 2020/0344881 A1
(43) Pub. Date: Oct. 29, 2020

(54) BOARD JOINT STRUCTURE AND BOARD JOINT METHOD

(71) Applicant: Murata Manufacturing Co., Ltd., Nagaokakyo-shi (JP)

(72) Inventors: Daisuke TONARU, Nagaokakyo-shi (JP); Genro KATO, Nagaokakyo-shi (JP); Shinichi ARAKI, Nagaokakyo-shi (JP)

(21) Appl. No.: 16/926,954

(22) Filed: Jul. 13, 2020

Related U.S. Application Data
(63) Continuation of application No. PCT/JP2018/044187, filed on Nov. 30, 2018.

(30) Foreign Application Priority Data
Jan. 23, 2018 (JP) 2018-008721

(51) Int. Cl. H05K 1/14; H05K 3/34; H05K 3/28; H05K 1/18

(52) U.S. Cl. CPC H05K 1/144; H05K 3/341; H05K 2201/2036; H05K 1/181; H05K 2201/09372; H05K 3/28

(57) ABSTRACT

In a board joint structure, a first board (board) and a component (mounting board) are joined together by a conductive joint material and an insulating joint material. The first board includes a first insulating substrate including a first main surface, a first electrode pad provided on the first main surface, a spacer, and the like. At least a portion of the insulating joint material and the spacer are located between the first board and the component, and the first electrode pad is joined to a second electrode pad of the component with the conductive joint material. A region of the first main surface other than a region where the first electrode pad is provided is joined to the component with the insulating joint material.

### CROSS REFERENCE TO RELATED APPLICATIONS

This application claims the benefit of priority to Japanese Patent Application No. 2018-008721 filed on Jan. 23, 2018 and is a Continuation Application of PCT Application No. PCT/JP2018/044187 filed on Nov. 30, 2018. The entire contents of each application are hereby incorporated herein by reference.

### BACKGROUND OF THE INVENTION

### 1. Field of the Invention

The present invention relates to a board joint structure, and more particularly to a board joint structure and a board joint method using a conductive joint material and an insulating joint material.

### 2. Description of the Related Art

A conventional method for surface-mounting (joining) a mounting board such as an electronic component using a conductive joint material and an insulating joint material (for example, underfill) is known.

For example, JP 5160813 B2 discloses a board joint structure where an electrode of a board and an electrode of a mounting board are joined together with a conductive joint material. Then, in order to increase joint strength (mechanical strength of a joint portion) between the mounting board and the board, a surface of the board and the mounting board are joined together with an insulating joint material.

Examples of the method for joining a mounting board to a board using a conductive joint material and an insulating joint material include the following method.

First, the mounting board is surface-mounted on the board with the conductive joint material, and then the insulating joint material is injected into a gap between the surface of the board and the mounting board.

The board or the mounting board is pre-coated with the conductive joint material and the insulating joint material. Then, heat and pressure are applied to the board and the mounting board stacked to join the mounting board to the board.

However, when the mounting board is mounted on the board by the above-described method, the following problems arise, thereby making it difficult to join the mounting board to the board using the insulating joint material.

When the mounting board is first surface-mounted on the board with the conductive joint material, it is likely that no gap is provided between the surface of the board and the mounting board or that, even if a gap is provided, the gap will be very narrow. This makes it difficult to inject the insulating joint material between the surface of the board and the mounting board, preventing sufficient joint strength between the board and the mounting board from being provided.

Further, when the mounting board is placed on top of the board and then heated and pressed, molten conductive joint material is extruded by the insulating joint material or the like, and thereby may cause a poor joint or poor conduction between the board and the mounting board.

### SUMMARY OF THE INVENTION

Preferred embodiments of the present invention provide, in a structure where a mounting board is joined to a board by a conductive joint material and an insulating joint material, a board joint structure that is able to significantly reduce or prevent a poor joint or poor conduction between the board and the mounting board while securing joint strength between the board and the mounting board.

A board joint structure according to a preferred embodiment of the present invention includes a board and a mounting board. The board and the mounting board are joined together by a conductive joint material and an insulating joint material. The board includes a first insulating substrate including a first main surface, a first electrode pad provided on the first main surface, and a plurality of spacers provided on the first main surface and being thicker than the first electrode pad. The mounting board includes a second electrode pad. The plurality of spacers are located at predetermined intervals, and the first electrode pad is surrounded by the plurality of spacers. At least a portion of the mounting board is placed over the board in plan view of the first main surface. At least a portion of the insulating joint material and the plurality of spacers are located between the board and the mounting board, and the first electrode pad is joined to the second electrode pad with the conductive joint material. At least a portion of an overlapping region of the first main surface overlapping the mounting board in plan view is joined to the mounting board by the insulating joint material.

The spacers that are thicker than the first electrode pads are located between the board and the mounting board. This provides, after the board and the mounting board are joined together by the conductive joint material, a gap between the board and the mounting board. Accordingly, the injection of the insulating joint material into the gap is facilitated and thus an increase joint strength with the mounting board is able to be provided.

Further, the spacers that are thicker than the first electrode pads are located between the board and the mounting board. After the board and the mounting board are joined together by a hot bar, the spacers significantly reduce or prevent the occurrence of a portion where the board and the mounting board are poorly joined together by the insulating joint material. Accordingly, a poor joint between the board and the mounting board with the insulating joint material is less likely to occur. Furthermore, a poor joint and poor conduction is able to be significantly reduced or prevented at a joint section between the first electrode pad and the second electrode pad due to extrusion of the conductive joint material by the insulating joint material during application of heat and pressure by the hot bar.

A protective film may be provided on the first main surface, and the spacer may be provided on a surface of the protective film.

The spacer may be a protrusion of the first insulating substrate provided on the first main surface.

The mounting board may include a portion that is not placed over the board.

A plurality of the spacers may be provided at predetermined intervals and surround the first electrode pad. After the mounting board and the board are joined together by the conductive joint material, the insulating joint material is thus able to be easily injected into the gap between the mounting board and the board from a plurality of directions. Further, by locating the plurality of spacers at predetermined intervals, the flow of the insulating joint material injected into the gap between the mounting board and the board from is able to be prevented from being hindered by the spacers.

The spacer may continuously surround the first electrode pad. At the time of joining the board and the mounting board, the spacer is able to define and function as a bank to significantly reduce or prevent entry of the insulating joint material into an inner region of the spacer. Accordingly, a poor joint and poor conduction due to extrusion of the conductive joint material by the insulating joint material at the time of joining are able to be significantly reduced or prevented.

A plurality of the spacers, a plurality of the first electrode pads and a plurality of the second electrode pads may be provided, and the plurality of spacers may respectively surround the plurality of first electrode pads. Accordingly, a poor joint and poor conduction at the joint sections of the first electrode pads due to entry of the insulating joint material into inner regions of the spacers is significantly reduced or prevented as compared to a structure in which one spacer surrounds the plurality of first electrode pads. More specifically, during application of heat and pressure by the hot bar, even when a poor joint occurs at the joint section of one of the first electrode pads due to extrusion of the conductive joint material by the insulating joint material, a poor joint at the joint section of the other of the first electrode pads is less likely to occur.

The first electrode pads may be out of contact with the insulating joint material. Accordingly, a poor joint and poor conduction are able to be reduced or prevented from occurring due to extrusion of the conductive joint material by the insulating joint material at the time of joining the board and the mounting board.

The first insulating substrate may be flexible. Accordingly, even when the mounting board comes into contact with the board during application of heat and pressure by the hot bar, the first insulating substrate is able to be deformed (define and function as a shock absorber) to significantly reduce or prevent damage to the board or the mounting board.

The first insulating substrate may have a bent portion. Accordingly, the degree of flexibility in placement of the board is able to be increased, and the board is able to be easily connected to another board or the like. Note that when the first insulating substrate has the bent portion, a joint portion between the board and the mounting board may separate due to bending stress or bending work. Since the joint strength between the board and the mounting board is secured, separation of the joint portion is able to be significantly reduced or prevented even when the first insulating substrate has the bent portion.

The spacer may have a thickness of from about 20 μm to about 100 μm both inclusive. When the spacer has a thickness of less than about 20 μm, the gap between the board and the mounting board becomes narrow, and the injection of the insulating joint material may be difficult. On the other hand, when the spacer has a thickness of greater than about 100 μm, the gap between the board and the mounting board becomes large, and the joint with the conductive joint material may be difficult. Therefore, the spacer preferably has a thickness of from about 20 μm to about 100 μm both inclusive.

A board joint method according to a preferred embodiment of the present invention is a board joint method for joining a mounting board and a board together, the board including a first insulating substrate including a first main surface, a plurality of first electrode pads provided on the first main surface, and a plurality of spacers provided on the first main surface and being thicker than the first electrode pads, the mounting board including a second electrode pad, the plurality of spacers being located at predetermined intervals, the first electrode pad being surrounded by the plurality of spacers. The board joint method includes a first process of providing the mounting board on the first main surface with the spacers located between the board and the mounting board, a second process of joining the first electrode pads and the second electrode pad together by a conductive joint material after the first process, and a third process of injecting an insulating joint material into a gap between the mounting board and the board after the second process.

A board joint method according to a preferred embodiment of the present invention is a board joint method for joining a mounting board and a board together, the board including a first insulating substrate including a first main surface, a plurality of first electrode pads provided on the first main surface, and a plurality of spacers provided on the first main surface and being thicker than the first electrode pads, the plurality of spacers each surrounding a corresponding one of the first electrode pads, the mounting board including a second electrode pad. The board joint method includes a fourth process of pre-coating at least either the first electrode pads or the second electrode pad with a paste conductive joint material, a fifth process of pre-coating a region of the first main surface other than a region where the first electrode pads and the spacers are provided or a surface of the mounting board with an insulating joint material, a sixth process of stacking the board and the mounting board with the spacers located between the board and the mounting board after the fourth process and the fifth process, and a seventh process of applying heat and pressure to the board and the mounting board stacked to join the first electrode pads and the second electrode pad together with the conductive joint material and to join at least a portion of an overlapping region of the first main surface overlapping the mounting board in plan view and the mounting board together with the insulating joint material, after the sixth process.

The above joint methods are each able to significantly reduce or prevent a poor joint and poor conduction between the board and the mounting board while securing joint strength between the board and the mounting board.

The first insulating substrate may be flexible, and a process of bending the first insulating substrate may be provided after the third process.

The first insulating substrate may be flexible, and a process of bending the first insulating substrate may be provided after the seventh process.

According to preferred embodiments of the present invention, in a structure where the mounting board is joined the board with the conductive joint material and the insulating joint material, a structure that is able to significantly reduce or prevent a poor joint or poor conduction between the board and the mounting board is able to be provided while also securing the joint strength between the board and the mounting board.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a cross-sectional view of a main portion of an electronic device 301 according to a first preferred embodiment of the present invention, and FIG. 1B is a plan view of a first board 101 of the electronic device 301.

FIGS. 2-1, 2-2, and 2-3 are cross-sectional views of the first board 101 and a component 1 according to the first preferred embodiment of the present invention, showing, sequentially, the process of joining the first board 101 and the component 1.

FIG. 3 is a plan view of a first board 102 according to a second preferred embodiment of the present invention.

FIG. 4A is a cross-sectional view of a first board 103A according to a third preferred embodiment of the present invention, and FIG. 4B is a cross-sectional view of another first board 103B according to the third preferred embodiment of the present invention.

FIG. 5 is an external perspective view of a main portion of a cable 401 according to a fourth preferred embodiment of the present invention.

FIG. 6A is an enlarged cross-sectional view of a joint portion between a first board 104 and a second board 201 according to the fourth preferred embodiment of the present invention, and FIG. 6B is a plan view of the first board 104.

FIG. 7 is a perspective view of a main portion of an electronic device 302 according to the fourth preferred embodiment of the present invention.

FIGS. 8-1 and 8-2 are enlarged cross-sectional views of the first board 104 and the second board 201 according to the fourth preferred embodiment of the present invention, showing, sequentially, the process of joining the first board 104 and the second board 201.

FIG. 9A is an enlarged cross-sectional view of a joint portion between a first board 105 and a second board 201 of a cable 402 according to a fifth preferred embodiment of the present invention, and FIG. 9B is a plan view of the first board 105.

FIG. 10 is an enlarged cross-sectional view of a joint portion between a first board 106 and a second board 202 of a cable 403 according to a sixth preferred embodiment of the present invention.

### DETAILED DESCRIPTION OF THE PREFERRED EMBODIMENTS

Hereinafter, preferred embodiments of the present invention will be described with reference to the drawings and some specific examples. In the drawings, the same portions are denoted by the same reference numerals. Although the preferred embodiments will be described separately, for the sake of convenience, in consideration of easy explanation or understanding of the gist, some components shown in different preferred embodiments may be replaced or combined with one another. In second and subsequent preferred embodiments, no description will be provided of points common to a first preferred embodiment, and only differences will be described. In particular, no description will be provided of the same or similar advantageous features and effects of the same or similar features one by one for each preferred embodiment.

### First Preferred Embodiment

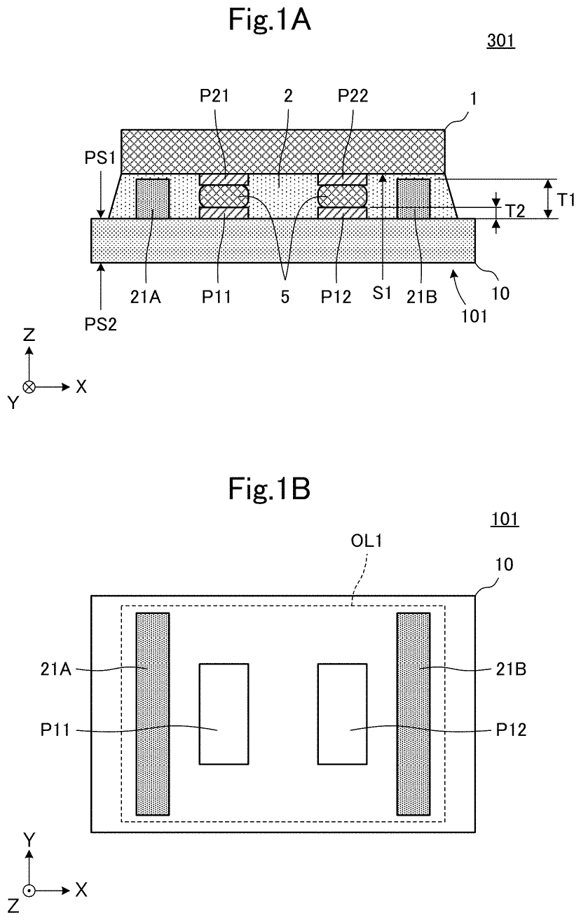

FIG. 1A is a cross-sectional view of a main portion of an electronic device 301 according to a first preferred embodiment of the present invention. FIG. 1B is a plan view of a first board 101 of the electronic device 301. In FIG. 1B, for easy understanding of the structure, spacers 21A, 21B are shown as a dot pattern, and an overlapping region OL1 is shown as a dashed line.

The electronic device 301 includes the first board 101, a component 1, and the like. The component 1 is mounted on (joined to) the first board 101 by a conductive joint material 5 and insulating joint material 2. Note that a board other than the component 1, an electronic component, and the like are mounted on the first board 101, but they are not shown.

In the first preferred embodiment, the component 1 corresponds to a “mounting board”.

The component 1 is, for example, a chip component such as a chip inductor or a chip capacitor, an IC, an RFIC element, an impedance matching circuit, or the like. The first board 101 is a printed wiring board, for example, a glass/epoxy board. The conductive joint material 5 is, for example, solder or the like, and the insulating joint material 2 is, for example, underfill or the like. The material of the underfill may include a thermosetting resin, for example, an epoxy resin, a thermoplastic resin, for example, an acrylic resin, and the like.

The first board 101 includes a first insulating substrate 10, first electrode pads P11, P12, the spacers 21A, 21B, and the like. Note that the first board 101 includes elements (a conductor, a component, or the like) in addition to those described above, but the elements are not shown.

The first insulating substrate 10 is, for example, a rectangular or substantially rectangular insulating flat plate and includes a first main surface PS1 and a second main surface PS2 on opposite sides of the first insulating substrate 10. On the first main surface PS1 of the first insulating substrate 10, the first electrode pads P11, P12 and the spacers 21A, 21B are provided. The first electrode pads P11, P12 are, for example, rectangular or substantially rectangular conductor patterns. The spacers 21A, 21B are, for example, linear or substantially linear components that protrude from the first main surface PS1 of the first insulating substrate 10 in a +Z direction and extend along a Y-axis. The spacers 21A, 21B are components that are not melted during a heat process (described below) performed when the component 1 is joined to the first board 101. The first electrode pads P11, P12 are each a conductor pattern made of, for example, a Cu foil. The spacers 21A, 21B are each, for example, an epoxy resin film, a polyimide film, a solder resist film, a coverlay film, a flat metal plate such as, a stainless steel plate, or the like, for example.

As shown in FIG. 1A, a thickness (T1) of the spacers 21A, 21B is larger than a thickness (T2) of the first electrode pads P11, P12 (T1>T2). Note that, in the first preferred embodiment, the thickness (T1) of the spacers 21A, 21B is, for example, from about 20 μm to about 100 μm both inclusive.

The component 1 includes second electrode pads P21, P22. The second electrode pads P21, P22 are provided on a first surface S1 of the component 1.

As shown in FIG. 1A, the component 1 is placed over the first board 101 in plan view of the first main surface PS1 (when viewed along a Z-axis). Further, the first surface S1 of the component 1 faces the first main surface PS1 of the first board 101. A portion of the insulating joint material 2 and the spacers 21A, 21B are located between the component 1 and the first board 101.

The first electrode pads P11, P12 are respectively connected to the second electrode pads P21, P22 with the conductive joint material 5. The overlapping region (see the overlapping region OL1 in FIG. 1B) of the first main surface PS1 overlapping the component 1 in plan view (when viewed along the Z-axis) is joined to the component 1 with the insulating joint material 2. More specifically, a region of the overlapping region OL1 other than a region where the first electrode pads P11, P12 are provided is joined to the first surface S1 of the component 1 with the insulating joint material 2.

As shown in FIGS. 1A, 1B, and the like, in the first preferred embodiment, with the first board 101 and the component 1 (mounting board) joined together, the spacers 21A, 21B are not directly in contact with the component 1, or alternatively, the spacers 21A, 21B may be in direct contact with component 1.

The component 1 (mounting board) is joined to the first board 101 by, for example, a joint method described below. FIGS. 2-1, 2-2, and 2-3 are cross-sectional views of the first board 101 and the component 1 according to the first preferred embodiment, showing, sequentially, the process of joining the first board 101 and the component 1.

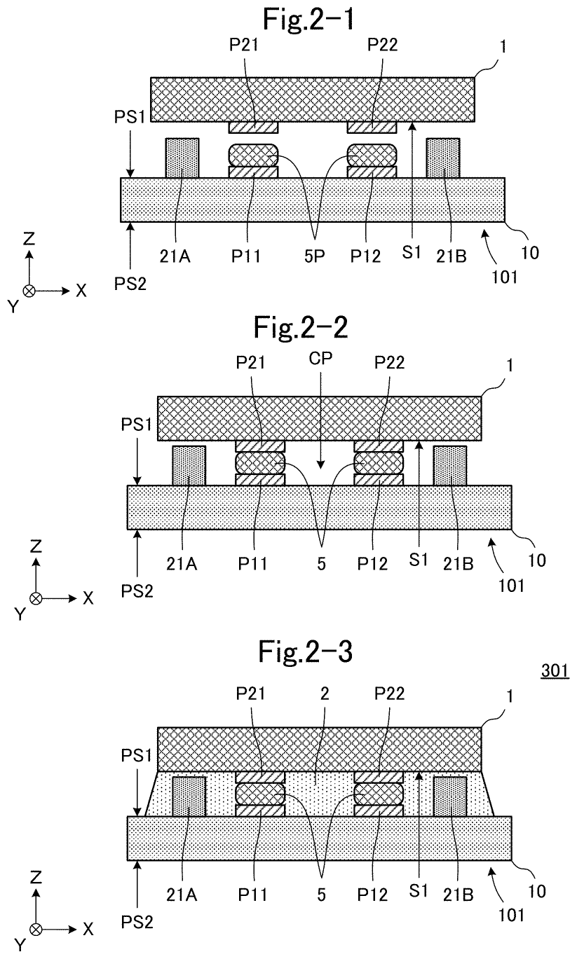

First, as shown in FIG. 2-1, the first board 101 and the component 1 are prepared. Note that respective surfaces of the first electrode pads P11, P12 of the first board 101 are pre-coated with a conductive paste 5P (paste conductive joint material) The conductive paste 5P is preferably, for example, a solder paste. Note that only the surfaces of the second electrode pads P21, P22 may be pre-coated with the conductive paste 5P. Alternatively, all surfaces of the first electrode pads P11, P12 and the second electrode pads P21, P22 may be pre-coated.

Next, the component 1 is placed (stacked) on the first main surface PS1 of the first insulating substrate 10 with the spacers 21A, 21B located between the first board 101 and the component 1. Specifically, the component 1 is provided on the first board 101 to cause the first electrode pads P11, P12 and the second electrode pads P21, P22 to face each other.

This process of stacking the first board 101 and the component 1 (mounting board) with the spacers 21A, 21B located between the first board 101 and the component 1 is an example of a “first process.”

Next, as shown in FIG. 2-2, the component 1 is joined to the first board 101 with the conductive joint material 5. More specifically, the conductive paste 5P is melted to become the conductive joint material 5 during a reflow process. This causes the first electrode pad P11 and the second electrode pad P21 to be joined together by the conductive joint material 5. Further, the first electrode pad P12 and the second electrode pad P22 are joined together by the conductive joint material 5.

This process of joining the first electrode pads P11, P12 and the second electrode pads P21, P22 with the conductive joint material 5 after the “first process” is an example of a “second process.”

Note that since the spacers 21A, 21B that are thicker than the first electrode pads P11, P12 are located between the first board 101 and the component 1, a gap CP is provided between the component 1 and the first board 101 after the reflow process.

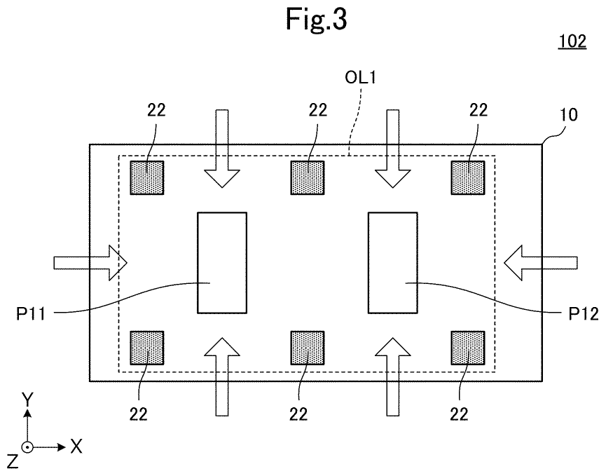

Then, as shown in FIG. 2-3, the insulating joint material 2 is injected into the gap CP between the first board 101 and the component 1. The insulating joint material 2 is, for example, underfill. This causes the overlapping region (see the overlapping region OL1 in FIG. 1B) of the first main surface PS1 overlapping the component 1 in plan view (when viewed along the Z-axis) to be joined to the component 1 with the insulating joint material 2.

This process of injecting the insulating joint material 2 into the gap CP between the component 1 (mounting board) and the first board 101 after the “second process” is an example of a “third process.”

The first preferred embodiment has the following advantageous effects.

The component 1 is joined to the first board 101 with the conductive joint material 5. Then, when the insulating joint material 2 is injected into the gap CP between the first board 101 and the component 1, it is difficult to inject the insulating joint material 2 if the gap CP is narrow. Further, the occurrence of a portion in the gap CP where the insulating joint material 2 is not injected may prevent sufficient joint strength between the first board 101 and the component 1 from being provided. On the other hand, in the electronic device 301 according to the first preferred embodiment, the spacers 21A, 21B that are thicker than the first electrode pads P11, P12 are located between the first board 101 and the component 1. Accordingly, after the first board 101 and the component 1 are joined together by the conductive joint material 5, the gap CP is provided between the first board 101 and the component 1 to facilitate the injection of the insulating joint material 2 into the gap CP. Thus, the joint strength between the first board 101 and the component 1 is able to be increased while significantly reducing or preventing a poor joint or poor conduction between the first board 101 and the component 1.

The thickness (T1) of the spacers 21A, 21B is not limited to a specific thickness, but is preferably, for example, from about 20 μm to about 100 μm both inclusive. When the thickness (T1) of the spacers 21A, 21B is smaller than about 20 μm, the gap CP between the first board 101 and the component 1 becomes narrow, and the injection of the insulating joint material 2 may be difficult (particularly, when a diameter of filler included the insulating joint material 2 is large). On the other hand, when the thickness (T1) of the spacers 21A, 21B is larger than about 100 μm, the gap CP between the component 1 and the first board 101 becomes large, and the joint with the conductive joint material may be difficult. Therefore, the thickness (T1) of the spacers 21A, 21B is preferably, for example, between about 20 μm and about 100 μm.

### Second Preferred Embodiment

In a second preferred embodiment of the present invention, a description will be provided of an example that differs from the first preferred embodiment in structure of the spacer.

FIG. 3 is a plan view of a first board 102 according to the second preferred embodiment. In FIG. 3, for easy understanding of the structure, spacers 22 are shown as a dot pattern, and the overlapping region OL1 is shown as a dashed line.

The first board 102 differs from the first board 101 according to the first preferred embodiment in that the first board 102 includes six spacers 22. Further, the spacers 22 differ from the spacers 21A, 21B according to the first preferred embodiment in shape and arrangement. The first board 102 is substantially identical in other features, components, and elements as the first board 101.

A description will be provided below of differences from the first board 101 according to the first preferred embodiment.

The spacers 22 have, for example, a rectangular or substantially rectangular shape in plan view. Note that, although not shown, the spacers 22 are thicker than the first electrode pads P11, P12. As shown in FIG. 3, the six spacers 22 are located at predetermined intervals to surround the first electrode pads P11, P12.

Note that, “located at predetermined intervals” corresponds to the following case, for example. (1) After joining the board and the mounting board with the conductive joint material, the plurality of spacers are provided at intervals to allow the insulating joint material to be injected into the gap between the board and the mounting board from a plurality of directions. (2) The plurality of spacers are located at intervals to not hinder the flow of the insulating joint material injected into the gap between the board and the mounting board. (3) When at least either the board or the mounting board is flexible, the plurality of spacers are located at intervals to prevent the board or the mounting board from being deformed and bent.

According to the second preferred embodiment, since three or more spacers 22 are provided, the insulating joint material is able to be injected into the overlapping region OL1 from a plurality of directions (see white arrows in FIG. 3).

Further, in the second preferred embodiment, the plurality of spacers 22 are located at predetermined intervals. Accordingly, after the first board 102 (board) and the mounting board are joined together by the conductive joint material, the insulating joint material is able to be easily injected into the gap (see the gap CP in FIGS. 2-1, 2-2, and 2-3) between the first board 102 and the mounting board from a plurality of directions. Further, by locating the plurality of spacers 22 at predetermined intervals, the flow of the insulating joint material injected into the gap between the first board 102 and the mounting board is able to be prevented from being hindered by the spacers. Accordingly, the joint strength between the first board 102 and the mounting board is able to be increased.

### Third Preferred Embodiment

In a third preferred embodiment of the present invention, a description will be provided of an example where a protective layer is provided on the first main surface.

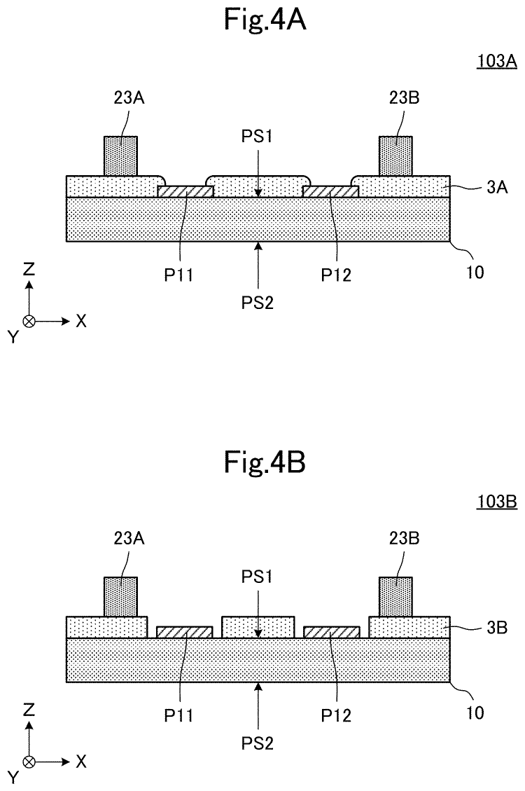

FIG. 4A is a cross-sectional view of a first board 103A according to the third preferred embodiment, and FIG. 4B is a cross-sectional view of another first board 103B according to the third preferred embodiment.

The first board 103A differs from the first board 101 according to the first preferred embodiment in that the first board 103A includes a protective film 3A. The first board 103B differs from the first board 101 in that the first board 103B includes a protective film 3B. The first boards 103A, 103B are substantially identical in other features, components, and elements as the first board 101.

A description will be provided below of differences from the first board 101 according to the first preferred embodiment.

As described above, the first board 103A further includes the protective film 3A. The protective film 3A is an insulating film provided almost over the first main surface PS1 of the first insulating substrate 10. The protective film 3A includes openings at positions corresponding to the first electrode pads P11, P12. Therefore, the protective film 3A provided on the first main surface PS1 partially exposes the first electrode pads P11, P12 on the first main surface PS1. As shown in FIG. 4A, the protective film 3A covers a portion of the first electrode pads P11, P12. That is, the protective film 3A has an over-resist structure with respect to the first electrode pad P11, P12. Further, spacers 23A, 23B are provided on a surface (the first main surface PS1 side) of the protective film 3A. The protective film 3A is preferably, for example, an epoxy resin film, a solder resist film, a coverlay film, or the like.

Further, the first board 103B further includes the protective film 3B. The protective film 3B is an insulating film provided almost over the first main surface PS1 of the first insulating substrate 10. The protective film 3B includes openings at positions corresponding to the first electrode pads P11, P12. Therefore, the protective film 3B provided on the first main surface PS1 partially exposes the first electrode pads P11, P12 on the first main surface PS1. As shown in FIG. 4B, the protective film 3B is provided apart from the first electrode pads P11, P12 with a gap provided between the protective film 3B and the first electrode pads P11, P12. That is, the protective film 3B has a clearance resist structure with respect to the first electrode pads P11, P12. Further, the spacers 23A, 23B are provided on a surface (the first main surface PS1 side) of the protective film 3B. The protective film 3B is preferably, for example, an epoxy resin film, a solder resist film, a coverlay film, or the like.

The structure and features described above provide the same or similar advantageous features and effects as described in the first preferred embodiment.

### Fourth Preferred Embodiment

In a fourth preferred embodiment of the present invention, a description will be provided of an example where the board and the mounting board are flexible.

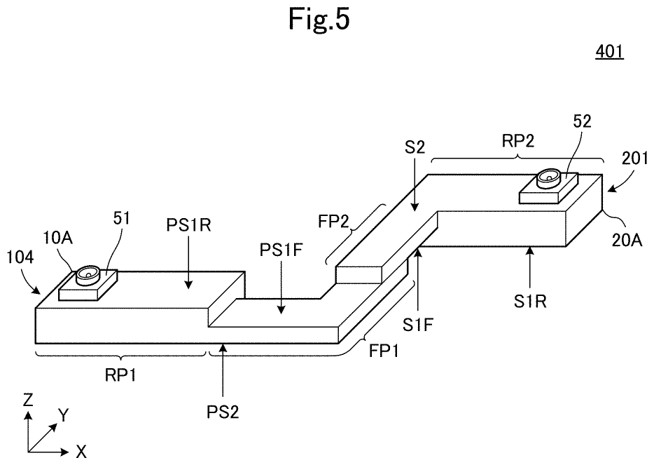

FIG. 5 is an external perspective view of a main portion of a cable 401 according to the fourth preferred embodiment. The cable 401 according to the present preferred embodiment is a flexible and crank-shaped (long) cable. The cable 401 includes a first board 104 and a second board 201 joined together by the conductive joint material and the insulating joint material.

In the present preferred embodiment, the second board 201 corresponds to a “mounting board.”

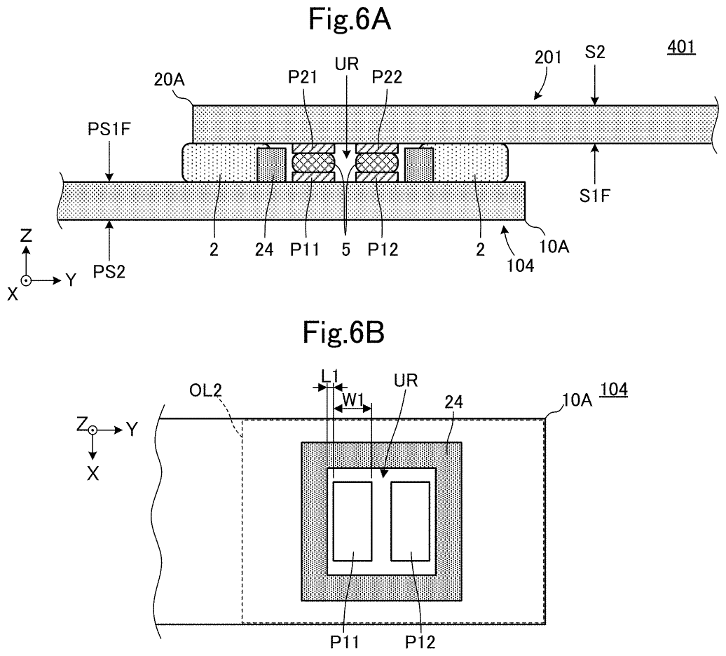

FIG. 6A is an enlarged cross-sectional view of a joint portion between the first board 104 and the second board 201 according to the fourth preferred embodiment, and FIG. 6B is a plan view of the first board 104. In FIG. 6B, for easy understanding of the structure, a spacer 24 is shown as a dot pattern, and an overlapping region OL2 is shown as a dashed line.

The first board 104 includes a first insulating substrate 10A, the first electrode pads P11, P12, the spacer 24, a connector 51, and the like. Note that the first board 104 includes a signal conductor, a ground conductor, and the like in addition to those described above, but they are not shown. The first board 104 differs from the first board 101 according to the first preferred embodiment in shape and material of the first insulating substrate 10A. Further, the first board 104 differs from the first board 101 in that the first board 104 further includes the connector 51.

A description will be provided below of differences from the first board 101 according to the first preferred embodiment.

The first insulating substrate 10A is an L-shaped (long) insulating flat plate whose longitudinal axis coincides with an X-axis and has first main surfaces PS1F, PS1R and a main surface PS2 on opposite sides of the first insulating substrate 10A. The first insulating substrate 10A is a resin flat plate including a laminate of a plurality of insulating substrate layers preferably made of, for example, a thermoplastic resin. In addition, first insulating substrate 10A is flexible.

In the present preferred embodiment, the first main surface PS1F of the first insulating substrate 10A corresponds to the “first main surface.”

As shown in FIG. 5, the first insulating substrate 10A includes a rigid portion RP1 and a flexible portion FP1. The rigid portion RP1 is larger in lamination number of insulating substrate layers than the flexible portion FP1. Therefore, the rigid portion RP1 is harder and stiffer than the flexible portion FP1. Further, the flexible portion FP1 is suppler and more flexible than the rigid portion RP1.

The first electrode pads P11, P12 are, for example, rectangular or substantially rectangular conductor patterns provided on the first main surface PS1F. The first electrode pads P11, P12 are electrically connected to the signal conductor (not shown) of the first board 104. The first electrode pads P11, P12 are located adjacent to or in a vicinity of a first end of the first insulating substrate 10A (a right end of the first insulating substrate 10A in FIG. 5).

The spacer 24 is a ring-shaped spacer provided on the first main surface PS1F and provided adjacent to or in a vicinity of to the first electrode pads P11, P12. As shown in FIG. 6B, the spacer 24 continuously surrounds the first electrode pads P11, P12. Note that, although not shown, the spacer 24 is thicker than the first electrode pads P11, P12.

Note that, herein, “provided adjacent to or in a vicinity of to the first electrode pads” means that the spacer is provided within an area having a width substantially equal to or less than about three times a width of the first electrode pads and extending from the first electrode pads along a certain direction in plan view of the first main surface (when viewed along the Z-axis). In other words, when a distance (L1) between the spacer and the first electrode pads along a certain direction (for example, along the X-axis) is substantially equal to or less than about three times the width (W1) of the first electrode pads along a certain direction (L1≤3W1) (see FIG. 6B), it is said that the spacer is “provided adjacent to or in a vicinity of to the first electrode pads”.

The connector 51 is mounted on the first main surface PS1R of the first insulating substrate 10A and is provided adjacent to or in a vicinity of a second end of the first insulating substrate 10A (a left end of the first insulating substrate 10A in FIG. 5). The connector 51 is electrically continuous with the signal conductor, the ground conductor (not shown), and the like of the first board 104 (not shown).

Next, a description will be provided of the second board. The second board 201 includes a second insulating substrate 20A, the second electrode pads P21, P22, a connector 52, and the like. Note that the second board 201 includes a signal conductor, a ground conductor, and the like in addition to those described above, but they are not shown.

The second insulating substrate 20A is an L-shaped (long) insulating flat plate whose longitudinal axis coincides with the X-axis and has first surfaces S1F, S1R and a second surface S2 on opposite sides of the second insulating substrate 20A. The second insulating substrate 20A is a resin flat plate including a laminate of a plurality of insulating substrate layers preferably made of, for example, a thermoplastic resin. In addition, the second insulating substrate 20A is flexible.

As shown in FIG. 5, the second insulating substrate 20A includes a rigid portion RP2 and a flexible portion FP2. The rigid portion RP2 is larger in lamination number of insulating substrate layers than the flexible portion FP2. Therefore, the rigid portion RP2 is harder and stiffer than the flexible portion FP2. Further, the flexible portion FP2 is suppler and more flexible than the rigid portion RP2.

The second electrode pads P21, P22 are, for example, rectangular or substantially rectangular conductor patterns provided on the first surface S1F. The second electrode pads P21, P22 are electrically connected to the signal conductor (not shown) of the second board 201. The second electrode pads P21, P22 are located adjacent to or in a vicinity of a first end of the second insulating substrate 20A (a left end of the second insulating substrate 20A in FIG. 5).

The connector 52 is mounted on the second surface S2 of the second insulating substrate 20A and is provided adjacent to or in a vicinity of a second end of the second insulating substrate 20A (a right end of the second insulating substrate 20A in FIG. 5). The connector 52 is electrically continuous with the signal conductor, the ground conductor, and the like of the second board 201 (not shown).

As shown in FIG. 6A, the second board 201 overlaps the first board 104 in plan view of the first main surface PS1F (when viewed along the Z-axis). A portion of the insulating joint material 2 and the spacer 24 are located between the first board 104 and the second board 201. The first surface S1F of the second board 201 faces the first main surface PS1F of the first board 104. In the fourth preferred embodiment, the second board 201 (mounting board) includes a portion that is not placed over the first board 104.

As shown in FIG. 6A, the first electrode pads P11, P12 are respectively connected to the second electrode pads P21, P22 with the conductive joint material 5. At least a portion of the overlapping region OL2 (see the overlapping region OL2 in FIG. 6B) of the first main surface PS1F overlapping the second board 201 in plan view (when viewed along the Z-axis) is joined to the second board 201 by the insulating joint material 2. More specifically, a region of the overlapping region OL2 other than a region where the first electrode pads P11, P12 are provided is joined to the first surface S1F of the second board 201 with the insulating joint material 2. As described above, joining the first board 104 and the second board 201 together defines one cable 401. The insulating joint material 2 is an adhesive that is cured at approximately the same temperature as a melting temperature of the conductive joint material 5, and is preferably, for example, an adhesive including an epoxy thermosetting resin.

Note that, as shown in FIG. 6A, with the first board 104 and the second board 201 joined together, the first electrode pads P11, P12 and the conductive joint material 5 are out of contact with the insulating joint material 2.

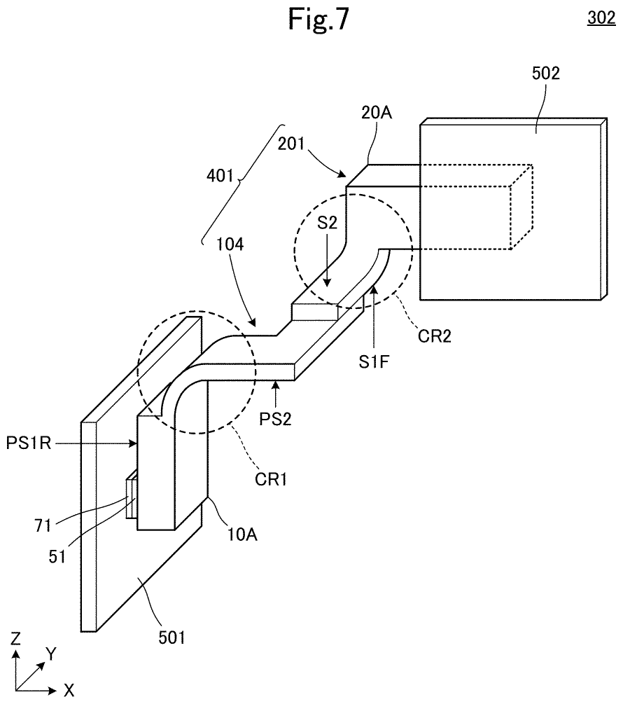

The cable 401 according to the fourth preferred embodiment is used, for example, as follows. FIG. 7 is a perspective view of a main portion of an electronic device 302 according to the fourth preferred embodiment.

The electronic device 302 includes the cable 401, mount boards 501, 502, and the like. A large number of electronic components and the like are mounted on the mount boards 501, 502, but the electronic components and the like are not shown. The mount boards 501, 502 are, for example, printed wiring boards.

As shown in FIG. 7, the cable 401 includes bent portions CR1, CR2. Specifically, the cable 401 is connected between the mount boards 501, 502 with the flexible portions (the flexible portion FP1 of the first board 104 and the flexible portion FP2 of the second board 201 shown in FIG. 5) bent. The connector 51 of the cable 401 is connected to a receptacle 71 mounted on the mount board 501. Further, the connector 52 of the cable 401 is connected to a receptacle (not shown) mounted on the mount board 502.

The second board 201 (mounting board) is joined to the first board 104 by, for example, a joint method described below. FIGS. 8-1 and 8-2 are enlarged cross-sectional views of the first board 104 and the second board 201 according to the fourth preferred embodiment, showing, sequentially, the process of joining the first board 104 and the second board 201.

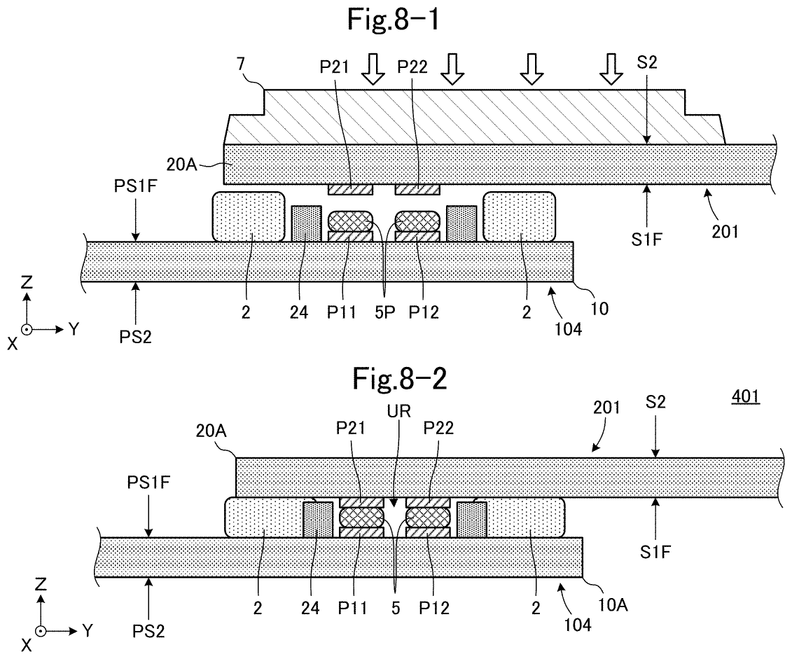

First, as shown in FIG. 8-1, the first board 104 and the second board 201 are prepared. Note that respective surfaces of the first electrode pads P11, P12 of the first board 104 are pre-coated with the conductive paste 5P (paste conductive joint material). Note that only the surfaces of the second electrode pads P21, P22 may be pre-coated with the conductive paste 5P, or alternatively, all surfaces of the first electrode pads P11, P12 and the second electrode pads P21, P22 may be pre-coated.

This process of pre-coating at least either the first electrode pads P11, P12 or the second electrode pads P21, P22 with the paste conductive joint material is an example of a “fourth process.”

Further, a region of the first main surface PS1F of the first insulating substrate 10A other than a region where the first electrode pads P11, P12 and the spacer 24 are located is pre-coated with the insulating joint material 2. Note that the first surface S1F of the second board 201 may be pre-coated with the insulating joint material 2. Further, both the first main surface PS1F of the first board 104 and the first surface S1F of the second board 201 may be pre-coated.

Note that, in the fourth preferred embodiment, the insulating joint material 2 is provided in a region of the first main surface PS1F outside a region where the spacer 24 is provided to continuously surround the first electrode pads P11, P12.

This process of pre-coating the region of the first main surface PS1F other than the region where the first electrode pads P11, P12 and the spacer 24 are provided or the first surface S1F of the second board 201 is pre-coated with the insulating joint material 2 is an example of a “fifth process.”

Then, the second board 201 is held by suction by a hot bar 7 and is placed (stacked) on the first main surface PS1F of the first board 104 with the spacer 24 and a portion of the insulating joint material 2 located between the first board 104 and the second board 201. Specifically, the second board 201 is provided on the first board 104 to cause the first electrode pads P11, P12 of the first board 104 and the second electrode pads P21, P22 of the second board 201 to face each other.

This process of stacking the first board 104 and the second board 201 with the spacer 24 provided between the first board 104 and the second board 201 after the “fourth process” and the “fifth process” is an example of a “sixth process.”

Then, the second board 201 is heated and pressed by the hot bar 7 in a stacking direction (−Z direction) (see a white arrow shown in FIG. 8-1), thereby joining the second board 201 to the first board 104. Accordingly, as shown in FIG. 8-2, the first electrode pads P11, P12 and the second electrode pads P21, P22 are joined by the conductive joint material 5. Further, the overlapping region (see the overlapping region OL2 in FIG. 6B) of the first main surface PS1F of the first board 104 overlapping the second board 201 in plan view (when viewed along the Z-axis) is joined, in part, to the second board 201 with the insulating joint material 2.

After the “sixth process”, the first board 104 and second board 201 thus stacked are heated and pressed. Then, the first electrode pads P11, P12 and the second electrode pads P21, P22 are joined together by the conductive joint material 5. Furthermore, at least a portion of the overlapping region of first main surface PS1F overlapping the second board 201 in plan view and second board 201 are joined together by the insulating joint material 2. This series of processes is an example of a “seventh process.”

Subsequently, a process of bending the first insulating substrate 10A of the first board 104 (or the second insulating substrate 20A of the second board 201) may be provided.

The fourth preferred embodiment has the following advantageous effects in addition to the advantageous effects described in the first preferred embodiment.

When a board including no spacer and a mounting board are joined together by the hot bar 7, excessive pressure is applied during application of heat and pressure to extrude the insulating joint material, which may generate a portion where the board and the mounting board are poorly joined together by the insulating joint material. This may lead to poor joint strength between the board and the mounting board. On the other hand, in the fourth preferred embodiment, since the spacer 24 thicker than the first electrode pads P11, P12 is provided between the first board 104 and the second board 201, the gap CP is provided between the first board 104 and the second board 201 after application of heat and pressure. This significantly reduces or prevents the occurrence of a portion where the first board 104 and the second board 201 are poorly joined together by the insulating joint material and significantly reduces or prevents the occurrence of a poor joint between the first board 104 and the second board 201 with the insulating joint material.

Further, when the board including no spacer and the mounting board are joined together by the hot bar 7, excessive pressure is applied to the joint section between the first electrode pads P11, P12 and the second electrode pads P21, P22. This may cause scattering or excessive wet-spreading of the conductive joint material from the joint section. Furthermore, excessive pressure is applied during application of heat and pressure to cause the insulating joint material 2 to extrude the conductive joint material 5 and may lead to poor conduction at the above-described joint section. On the other hand, in the fourth preferred embodiment, since the spacer 24 is provided between the first board 104 and the second board 201, application of excessive pressure to the joint section between the first electrode pads P11, P12 and the second electrode pads P21, P22 is able to be significantly reduced or prevented. Accordingly, changes in electrical characteristics due to scattering or excessive wet-spreading of the conductive joint material 5 from the above-described joint section during application of heat and pressure are able to be significantly reduced or prevented. Furthermore, a poor joint and poor conduction at the above-described joint section are able to be significantly reduced or prevented due to extrusion of the conductive joint material 5 by the insulating joint material 2 during application of heat and pressure.

In the fourth preferred embodiment, the first insulating substrate 10A of the first board 104 (or the second insulating substrate 20A of the second board 201) is flexible and long. With the insulating substrate (the first insulating substrate 10A or the second insulating substrate 20A) that is flexible and long, when the board and the mounting board are joined together by reflow soldering, the mounting board is likely to deform and shift in position at the time of, for example, being placed on the board. Joining the mounting board to the board by the hot bar is suitable. However, when the mounting board is joined to the board by the hot bar, excessive pressure is applied during application of heat and pressure, and a gap between the board and the mounting board is not easily provided. Therefore, the advantageous features and effects obtained by providing the spacer are particularly effective when the insulating substrate is flexible and long.

In the fourth preferred embodiment, the spacer 24 continuously surrounds the first electrode pads P11, P12, and the insulating joint material 2 is provided in a region of the first main surface PS1F outside the region where the spacer 24 is provided. Accordingly, during application of heat and pressure by the hot bar 7 (at the time of joining the first board 104 and the second board 201), the spacer 24 is able to define and function as a bank to significantly reduce or prevent entry of the insulating joint material 2 from the outside of the spacer 24 into an inner region UR. Thus, during application of heat and pressure by the hot bar 7, a poor joint and poor conduction due to extrusion of the conductive joint material 5 by the insulating joint material 2 are able to be significantly reduced or prevented.

In the fourth preferred embodiment, with the first board 104 and the second board 201 joined together, the first electrode pads P11, P12 and the conductive joint material 5 are out of contact with the insulating joint material 2. This prevents, during application of heat and pressure by the hot bar 7, a poor joint and poor conduction due to extrusion of the conductive joint material 5 by the insulating joint material 2.

Further, in the fourth preferred embodiment, with the first board 104 and the second board 201 joined together, no insulating joint material 2 is provided in the inner region UR of the spacer 24. Accordingly, during application of heat and pressure by the hot bar 7, extrusion of the conductive joint material 5 by the insulating joint material 2 is able to be significantly reduced or prevented. Note that, in the fourth preferred embodiment, the example where no insulating joint material 2 is provided in the inner region UR of the spacer 24 has been described, but the preferred embodiments are not limited to the features, components, and elements described above. For example, the insulating joint material 2 may be provided in the inner region UR of the spacer 24.

In the fourth preferred embodiment, the first insulating substrate 10A of the first board 104 is flexible. Accordingly, even when the first board 104 comes into contact with the second board 201 during application of heat and pressure by the hot bar 7, the first insulating substrate 10A is able to deform (define and function as a shock absorber) to significantly reduce or prevent damage to the first board 104 or the second board 201. Note that the same or similar advantageous features and effects are able to be provided even when the second insulating substrate 20A of the second board 201 is flexible. Note that, in the fourth preferred embodiment, since both the first insulating substrate 10A and the second insulating substrate 20A are flexible, the above-described advantageous features and effects are improved.

In general, a mother board is manufactured and then divided into a plurality of pieces that define and function as cables or the like. However, when a mother board is divided into long (or large) elements, the number of elements thus provided is small. On the other hand, in the fourth preferred embodiment, joining the first board 104 and the second board 201 together defines one cable 401 (composite board). That is, since joining small pieces (the first board and the second board) divided from the mother board together defines one large board, the number of boards provided from the mother board (the number of provided boards) is able to be increased.

Further, the cable 401 according to the fourth preferred embodiment is a flexible and long cable. As shown in FIG. 7, the cable 401 is bent. This may cause the joint portion between the first board 104 and the second board 201 to separate due to bending stress. On the other hand, the fourth preferred embodiment provides high joint strength between the first board 104 and the second board 201 and thus the separation at the above-described joint portion is able to be significantly reduced or prevented.

Note that the bent portions CR1, CR2 may be subjected to bending work (work to maintain a bent state). Accordingly, the joint portion between the first board 104 and the second board 201 may separate due to the bending work. However, the fourth preferred embodiment provides high joint strength between the first board 104 and the second board 201 and thus separation at the above-described joint portion is able to be significantly reduced or prevented even when the bending work is applied.

In the fourth preferred embodiment, the first insulating substrate 10A of the first board 104 includes the bent portion CR1. Accordingly, the degree of flexibility in placement of the first board 104 is increased, and the first board 104 is able to be easily connected to another board or the like. Further, in the fourth preferred embodiment, the second insulating substrate 20A of the second board 201 includes the bent portion CR2. This increases the degree of flexibility in placement of the second board 201 and thereby allows the second board 201 to be easily connected to another substrate or the like.

### Fifth Preferred Embodiment

In a fifth preferred embodiment of the present invention, a description will be provided of an example that differs from the fourth preferred embodiment in structure of the spacer.

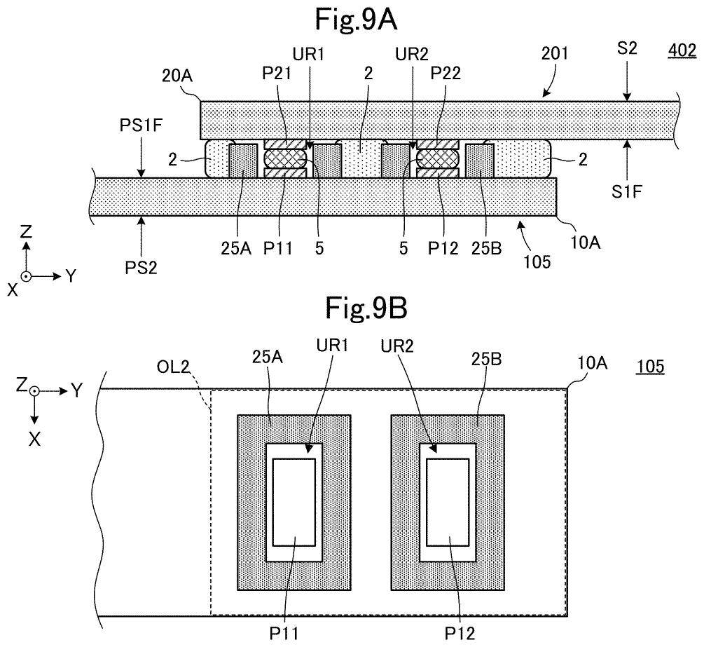

FIG. 9A is an enlarged cross-sectional view of a joint portion between a first board 105 and the second board 201 of a cable 402 according to the fifth preferred embodiment. FIG. 9B is a plan view of the first board 105. In FIG. 9B, for easy understanding of the structure, spacers 25A, 25B are shown as a dot pattern, and the overlapping region OL2 is shown as a dashed line.

The cable 402 according to the fifth preferred embodiment includes the first board 105 and the second board 201 joined together by the conductive joint material and the insulating joint material.

In the fifth preferred embodiment, the second board 201 corresponds to a “mounting board.” The second board 201 is the same as or similar to the second board 201 described in the fourth preferred embodiment.

The first board 105 includes the first insulating substrate 10A, the first electrode pads P11, P12, the spacers 25A, 25B, and the like. The first board 105 differs from the first board 104 according to the fourth preferred embodiment in that the first board 105 includes the spacers 25A, 25B. The first board 105 is substantially identical in other features, components, and elements as the first board 104.

A description will be provided below of differences from the first board 104 according to the fourth preferred embodiment.

The spacer 25A is a ring-shaped spacer provided on the first main surface PS1F and provided adjacent to or in a vicinity of to the first electrode pad P11. As shown in FIG. 9B, the spacer 25A continuously surrounds the first electrode pad P11. The spacer 25B is a ring-shaped spacer provided on the first main surface PS1F and provided adjacent to or in a vicinity of to the first electrode pad P12. The spacer 25B continuously surrounds the first electrode pad P12. As shown in FIG. 9A, the spacers 25A, 25B are thicker than the first electrode pads P11, P12.

As shown in FIG. 9A, a portion of the insulating joint material 2 and the spacers 25A, 25B are located between the first board 105 and the second board 201. The first surface S1F of the second board 201 faces the first main surface PS1F of the first board 105.

As shown in FIG. 9A, the first electrode pads P11, P12 are respectively joined to the second electrode pads P21, P22 with the conductive joint material 5. At least a portion of the overlapping region (see the overlapping region OL2 in FIG. 9B) of the first main surface PS1F overlapping the second board 201 in plan view (when viewed along the Z-axis) is joined to the second board 201 by the insulating joint material 2. More specifically, a region of the overlapping region other than a region where the first electrode pads P11, P12 are provided is joined to the first surface S1F of the second board 201 with the insulating joint material 2. As described above, joining the first board 105 and the second board 201 together defines one cable 402.

The fifth preferred embodiment has the following advantageous effects in addition to the advantageous effects described in the fourth preferred embodiment.

In the fifth preferred embodiment, the spacers 25A, 25B surround the first electrode pad P11 and the first electrode pad P12, respectively. Accordingly, as shown in FIG. 9A, the insulating joint material 2 is able to be provided between the spacers 25A, 25B with the first board 105 and the second board 201 joined together. Thus, the joint strength between the first board 105 and the second board 201 is able to be increased as compared to the structure in which one spacer surrounds a plurality of first electrode pads (refer to the fourth preferred embodiment).

Further, a poor joint and poor conduction at the joint sections of the first electrode pads P11, P12 due to entry of the insulating joint material 2 into inner regions UR1, UR2 of the spacers 25A, 25B are able to be significantly reduced or prevented as compared to the structure in which one spacer surrounds a plurality of first electrode pads. More specifically, during application of heat and pressure by the hot bar, even when a poor joint occurs at the joint section of one of the first electrode pads due to extrusion of the conductive joint material 5 by the insulating joint material 2, a poor joint at the joint section of the other of the first electrode pads is less likely to occur.

Further, even when the conductive joint material 5 is scattered or the like from the joint section of the first electrode pads P11, P12 during application of heat and pressure by the hot bar, a short circuit between the first electrode pads P11, P12 is able to be significantly reduced or prevented.

### Sixth Preferred Embodiment

In a sixth preferred embodiment of the present invention, a description will be provided of an example that differs from the above-described preferred embodiments in structure of the spacer.

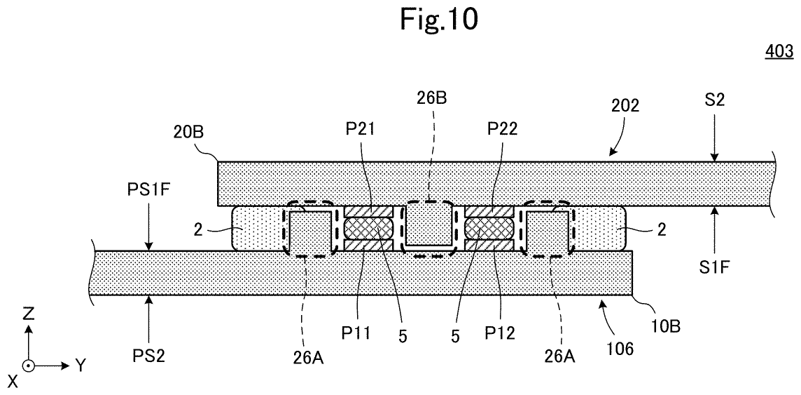

FIG. 10 is an enlarged cross-sectional view of a joint portion between a first board 106 and a second board 202 of a cable 403 according to the sixth preferred embodiment.

The cable 403 according to the sixth preferred embodiment includes the first board 106 and the second board 202 joined together by the conductive joint material 5 and the insulating joint material 2.

In the sixth preferred embodiment, the second board 201 corresponds to a “mounting board.”

The first board 106 includes a first insulating substrate 10B, the first electrode pads P11, P12, a spacer 26A, and the like. The first board 106 differs from the first board 104 according to the fourth preferred embodiment in that the spacer 26A is a portion of the first insulating substrate 10B.

A description will be provided below of differences from the first board 104 according to the fourth preferred embodiment.

The first insulating substrate 10B includes first main surfaces PS1F, PS1R and a second main surface PS2 on opposite sides of the first insulating substrate 10B. The first insulating substrate 10B is a resin flat plate including a laminate of a plurality of insulating substrate layers preferably made of, for example, a thermoplastic resin. In addition, first insulating substrate 10B is flexible.

The spacer 26A is a portion of the first insulating substrate 10B and is a ring-shaped protrusion provided on the first main surface PS1F. Although not shown, the spacer 26A continuously surrounds the first electrode pads P11, P12. Note that, as shown in FIG. 10, the spacer 26A is thicker than the first electrode pads P11, P12. The spacer 26A includes, for example, a laminate of insulating substrate layers that is larger in lamination number than the other portions. Further, the spacer 26A may be provided by grinding the first main surface PS1F of the first insulating substrate 10B with a laser or a drill.

Next, a description will be provided of the second board. The second board 202 includes a second insulating substrate 20B, the second electrode pads P21, P22, a spacer 26B, and the like. The second board 202 differs from the second board 201 according to the fourth preferred embodiment in that the second board 202 includes the spacer 26B.

A description will be provided below of differences from the second board 201 according to the first preferred embodiment.

The second insulating substrate 20B includes first surfaces S1F, S1R and a second surface S2 on opposite sides of the second insulating substrate 20B. The second insulating substrate 20B is a resin flat plate including a laminate of a plurality of insulating substrate layers preferably made of, for example, a thermoplastic resin. In addition, the second insulating substrate 20B is flexible.

The spacer 26B is a portion of the second insulating substrate 20B and is a linear or substantially linear protrusion provided on the first surface S1F. As shown in FIG. 10, the spacer 26B is thicker than the second electrode pads P21, P22. The spacer 26B includes, for example, a laminate of insulating substrate layers that is larger in lamination number than the other portions. Further, the spacer 26B may be provided by grinding the first surface S1F of the second insulating substrate 20B with a laser or a drill.

As shown in FIG. 10, the second board 202 partially overlaps the first board 106 in plan view of the first main surface PS1F (when viewed along the Z-axis). A portion of the insulating joint material 2 and the spacers 26A, 26B are located between the first board 106 and the second board 202. The first surface S1F of the second board 202 faces the first main surface PS1F of the first board 106.

As shown in FIG. 10, the first electrode pads P11, P12 are respectively joined to the second electrode pads P21, P22 with the conductive joint material 5. The overlapping region (see the overlapping region OL2 in FIG. 9B) of the first main surface PS1F overlapping the second board 202 in plan view (when viewed along the Z-axis) is joined to the second board 202 with the insulating joint material 2. More specifically, a region of the overlapping region other than the region where the first electrode pads P11, P12 are provided is joined to the first surface S1F of the second board 202 with the insulating joint material 2. As described above, joining the first board 106 and the second board 202 together defines one cable 403.

As described in the sixth preferred embodiment, the spacer may be a portion of the insulating substrate. Further, as described in the sixth preferred embodiment, both the board (first board) and the mounting board (second board) may include a spacer.

### Other Preferred Embodiments

In each of the preferred embodiments described above, examples where the first insulating substrate (first board) and the second insulating substrate (second board) are rectangular or substantially rectangular flat plates or L-shaped flat plates have been described. However, the shapes of the first insulating substrate and the second insulating substrate may be appropriately changed within a scope in which the advantageous features and effects described above are able to be provided. The first insulating substrate and the second insulating substrate may have, for example, a polygonal shape, a circular shape, an elliptical shape, an arc shape, a U-shape, a Y-shape, a T-shape, a crank shape, or the like in plan view. Furthermore, in each of the preferred embodiments described above, the example where the cable has a crank shape has been described, but the shape of the cable may be appropriately changed within a scope in which the features and effects described above are able to be provided. For example, the shape may be a linear or substantially linear shape, an arc shape, an L-shape, a C-shape, a U-shape, or the like.

In each of the preferred embodiments described above, examples where the first board (first insulating substrate) is a resin flat plate made of a thermosetting resin or a thermoplastic resin have been described, but the preferred embodiments of the present invention are not limited to these features, components, and elements. The first insulating substrate may be, for example, a dielectric ceramic, for example, a low-temperature co-fired ceramic (LTCC). Further, the first insulating substrate may be a composite laminate of a plurality of resins. Further, the composite laminate of a plurality of resins is a laminate of, for example, a thermosetting resin such as a glass/epoxy board and a thermoplastic resin. Further, when the first insulating substrate is a laminate, the first insulating substrate is not limited to surfaces of a plurality of insulating substrate layers being fused together through application of heat and pressure to a laminate of the plurality of insulating substrate layers, and an adhesive layer may be provided between the insulating substrate layers. The same or similar features apply to the second board (second insulating substrate).

In each of the preferred embodiments described above, examples where the spacer has a linear or substantially linear shape, a ring shape, or a rectangular or substantially rectangular shape have been described, but the shape of the spacer is not limited to these shapes. The shape of the spacer may be appropriately changed within a scope in which the advantageous features and effects described above are able to be provided. For example, the shape may be a circular or substantially circular shape, an elliptical shape, an arc shape, an L-shape, a U-shape, a T-shape, a Y-shape, a crank-shape, or the like. Further, the number of spacers may be appropriately changed.

Further, in each of the preferred embodiments described above, examples where the first electrode pads and the second electrode pads are rectangular or substantially rectangular conductor patterns have been described, but the present invention are not limited to these features, components, and elements. The shape, number, and the like of the first electrode pads and the second electrode pads may be appropriately changed within a scope in which the advantageous features and effects described above are able to be provided. The first electrode pads and the second electrode pads may have, for example, a linear or substantially linear shape, a polygonal shape, a circular or substantially circular shape, an elliptical shape, an arc shape, a ring shape, an L-shape, a U-shape, a T-shape, a Y-shape, a crank shape, or the like.

Note that, on the first board and the second board, conductor patterns other than the first electrode pads, the second electrode pads, the signal conductor, and the ground conductor may be provided. Further, the circuits provided on the first board and the second board may be appropriately changed within a scope in which the advantageous features and effects described above are able to be provided. Further, a frequency filter, for example, an inductor, a capacitor, or any type of filter (a low-pass filter, a high-pass filter, a band-pass filter, a band elimination filter) may include a conductor pattern on the first board or the second board. Further, various transmission lines (for example, a strip line, a microstrip line, a coplanar line, and the like) may be provided on the first board or the second board. Furthermore, various components, for example, chip components may be mounted on (or embedded in) the first board or the second board.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A board joint structure comprising:
a board; and
a mounting board; wherein
the board and the mounting board are joined together by a conductive joint material and an insulating joint material;
the board includes:
a first insulating substrate including a first main surface;
a first electrode pad provided on the first main surface; and
a plurality of spacers provided on the first main surface and being thicker than the first electrode pad;
the mounting board includes a second electrode pad;
the plurality of spacers are located at predetermined intervals;
the first electrode pad is surrounded by the plurality of spacers;
at least a portion of the mounting board is placed over the board in plan view of the first main surface;
at least a portion of the insulating joint material and the plurality of spacers are located between the board and the mounting board;
the first electrode pad is joined to the second electrode pad with the conductive joint material; and
at least a portion of an overlapping region of the first main surface overlapping the mounting board in plan view is joined to the mounting board by the insulating joint material.

2. The board joint structure according to claim 1, further comprising:
a protective film provided on the first main surface; wherein
the plurality of spacers are provided on a surface of the protective film.

3. The board joint structure according to claim 1, wherein the plurality of spacers are protrusions of the first insulating substrate provided on the first main surface.

4. The board joint structure according to claim 1, wherein the mounting board includes a portion that is not placed over the board.

5. The board joint structure according to claim 1, wherein a plurality of the first electrode pads and a plurality of the second electrode pads are provided, and the plurality of spacers each surround a corresponding one of the plurality of first electrode pads.

6. The board joint structure according to claim 5, wherein the plurality of first electrode pads are out of contact with the insulating joint material.

7. The board joint structure according to claim 1, wherein the first insulating substrate is flexible.

8. The board joint structure according to claim 1, wherein the first insulating substrate includes a bent portion.

9. The board joint structure according to claim 1, wherein the plurality of spacers have a thickness of from about 20 μm to about 100 μm both inclusive.

10. A board joint method for joining a mounting board and a board together, the board including a first insulating substrate including a first main surface, a plurality of first electrode pads provided on the first main surface, and a plurality of spacers provided on the first main surface and thicker than the first electrode pads, the mounting board including a second electrode pad, the plurality of spacers being located at predetermined intervals, the first electrode pads being surrounded by the plurality of spacers, the board joint method comprising:
stacking the board and the mounting board with the plurality of spacers located between the board and the mounting board;
joining the first electrode pads and the second electrode pad together by a conductive joint material; and
injecting an insulating joint material into a gap between the mounting board and the board.

11. A board joint method for joining a mounting board and a board together, the board including a first insulating substrate including a first main surface, a first electrode pad provided on the first main surface, and a plurality of spacers provided on the first main surface and thicker than the first electrode pad, the mounting board including a second electrode pad, the board joint method comprising:
pre-coating at least one of the first electrode pad and the second electrode pad with a paste conductive joint material;
pre-coating a region of the first main surface other than a region where the first electrode pad and the spacers are provided or a surface of the mounting board with an insulating joint material;
stacking the board and the mounting board with the spacers located between the board and the mounting board; and
applying heat and pressure to the board and the mounting board stacked to join the first electrode pad and the second electrode pad together with the conductive joint material and to join an overlapping region of the first main surface overlapping the mounting board in plan view and the mounting board together with the insulating joint material.

12. The board joint method according to claim 10, wherein
the first insulating substrate is flexible; and
the first insulating substrate is bent after the insulating joint material is injected into the gap between the mounting board and the board.

13. The board joint method according to claim 11, wherein
the first insulating substrate is flexible; and
the first insulating substrate is bent after the overlapping region and the mounting board are joined together.

14. The board joint structure according to claim 1, wherein the board is a printed wiring board and the mounting board is a chip component.

15. The board joint structure according to claim 1, wherein the insulating joint material includes a thermosetting resin.

16. The board joint structure according to claim 1, wherein the plurality of spacers includes six spacers.

17. The board joint structure according to claim 1, wherein the plurality of spacers are linear or substantially linear components that protrude from the first main surface of the board.

18. The board joint structure according to claim 1, wherein the plurality of spacers include a first plurality of spacers separated from one another by a first predetermined distance and a second plurality of spacers separated from one another by a second predetermined distance.

19. The board joint structure according to claim 2, wherein at least a portion of the first electrode pad is exposed through the protective film.
